(19) United States
(12) Patent Application Publication
(10) Pub. No.: US 2025/0026920 A1
(43) Pub. Date: Jan. 23, 2025

(54) LIQUID EPOXY RESIN COMPOSITION FOR USE AS MOLD UNDERFILL MATERIAL FOR TSV

(71) Applicants: SK hynix Inc., Icheon-si (KR); NAMICS CORPORATION, Niigata-shi (JP)

(72) Inventors: Minsuk KIM, Icheon-si (KR); Hyunsuk LEE, Icheon-si (KR); Sungho CHO, Icheon-si (KR); Tsuyoshi KAMIMURA, Niigata-shi (JP); Yosuke SAKAI, Niigata-shi (JP); Makoto SUZUKI, Niigata-shi (JP)

(73) Assignees: SK hynix Inc., Icheon-si (KR); NAMICS CORPORATION, Niigata-shi (JP)

(21) Appl. No.: 18/770,676

(22) Filed: Jul. 12, 2024

(30) Foreign Application Priority Data
Jul. 12, 2023 (JP) 2023-114447

(51) Int. Cl. C08K 13/06; C08G 59/62; H01L 21/56; H01L 23/00; H01L 23/29; H01L 25/065

(52) U.S. Cl. CPC C08K 13/06; C08G 59/621; H01L 21/565; H01L 23/295; H01L 24/16; H01L 24/27; H01L 24/29; H01L 24/32; H01L 24/73; C08K 2201/001; C08K 2201/005; C08K 2201/014; H01L 21/563; H01L 25/0652; H01L 25/0657; H01L 2224/16145; H01L 2224/27515; H01L 2224/2929; H01L 2224/29324; H01L 2224/29387; H01L 2224/29499; H01L 2224/32145; H01L 2224/73204; H01L 2225/06513; H01L 2225/06524; H01L 2225/06541; H01L 2924/3511; H01L 2924/381; H01L 2924/3841

(57) ABSTRACT

An object of the present invention is to provide a liquid epoxy resin composition suitable for use as a mold underfill material for TSV, which composition may provide an electronic component having high wiring density, satisfactorily releasing heat generated during its driving and having high reliability. The liquid epoxy resin composition of the present invention comprises an epoxy resin (A), a curing agent (B), an inorganic filler (C) consisting of a silica filler and an alumina filler and carbon black (D); the epoxy resin (A) comprises a specific aliphatic epoxy resin, the alumina filler has a specific particle size distribution, and the liquid epoxy resin composition gives a cured product having a thermal conductivity within a predetermined range. The liquid epoxy resin composition of the present invention gives a cured product having high thermal conductivity. Thus, in a semiconductor device that includes electronic components manufactured using the composition as a mold underfill material for TSV, deterioration of performance due to heat is suppressed. Furthermore, an electronic component manufactured using the liquid epoxy resin composition of the present invention as a mold underfill material for TSV exhibits sufficient reliability. Thus, the liquid epoxy resin composition of the present invention is highly suitable for use as a mold underfill material for TSV.

### BACKGROUND OF THE INVENTION

### Field of the Invention

The present invention relates to a liquid epoxy resin composition for use as a mold underfill material for TSV.

### Description of the Related Art

In recent years, with respect to wiring on chips in electronic components constituting electronic devices, further densification is desired for further improvement of performance of the electronic devices. However, increase of wiring density per unit area of a chip by further miniaturization of wiring is becoming close to limit. Thus, it is becoming general to further increase wiring density per unit area of a chip by three-dimensional stacking of a plurality of chips.

In such a technique, connection between the stacked chips is necessary. Through silicon via (TSV) technique is increasingly employed in such a connection. The TSV technique is a technique in which electrodes are provided on a silicon semiconductor chip, the electrodes penetrating the chip along the direction of the thickness of the chip, and the stacked chips are connected with these electrodes.

In the production of an electronic component comprising such a plurality of stacked chips, conventionally employed were the steps of carrying out, in each stacking of a chip, sealing between a wafer and a chip or between chips; entirely covering the stacked chips with a liquid curable resin composition; and subjecting the composition together with the chips to compression molding, to thereby mold the outer shape of the electronic component (overmolding). In recent years, however, more increasingly employed for improved production efficiency is a technique in which all chips are stacked without sealing, the stacked chips are entirely covered with a liquid curable resin composition and the composition is subjected to compression molding together with the chips so that sealing between a wafer and the chip and between each pair of chips and molding of the outer shape of the electronic component are carried out in one step. In such a process, a wafer level chip size packaging technique (in which a wafer after the completion of circuit formation, not cut into individual chips, is encapsulated as it is) is frequently used. A curable resin composition used in such a technique is referred to as a mold underfill material for TSV or a mold underfill composition for TSV. A liquid epoxy resin composition is mainly used as the mold underfill material for TSV. As used herein, an electronic component manufactured by the above technique, which includes chips (a kind of semiconductor devices) in an encapsulated state, is referred to as a “semiconductor package”.

Such mold underfill materials often contain fillers and/or colorants. The former is added mainly for reducing the coefficient of thermal expansion, improving the strength and the like in the cured products given by the mold underfill materials. Silica fillers are usually used as such fillers. The latter is added to reduce the effect of light on wiring in electronic components. In some cases, the former is added together with the latter to assist the function of the latter.

### CITATION LIST

### Patent Literature

Patent Literature 1: Japanese Patent Application No. 2022-010900
Patent Literature 2: Japanese Patent Application Kokai Publication No. 2021-172793
Patent Literature 3: WO 2019/131670
Patent Literature 4: Japanese Patent Application Kokai Publication No. 2017-179185

### SUMMARY OF THE INVENTION

A semiconductor device having electronic components with high wiring density, which components contain a plurality of three-dimensionally stacked chips, has a problem of lowering of its performance by heat generated during the driving of the electronic components. This problem is caused by short distance between the wafer and chip and/or between the chips as a result of densification of wiring, which results in difficulty in release of generated heat. The problem was more serious in a semiconductor device having electronic components manufactured using a mold underfill material containing a silica filler having low thermal conductivity.

Furthermore, a semiconductor device having electronic components with high wiring density as described above, the components having a plurality of bumps, has a problem in its reliability because of potential short circuiting between the bumps. This problem is becoming apparent because of further shortened distance between the bumps as a result of densification of wiring. Such a short circuiting tends to occur when the curable resin composition (for example, a mold underfill material for TSV) used for producing the electronic component has a high content of ionic impurities, in particular, chloride ions.

One of various conventionally known reliability tests for electronic components is high accelerated stress test (HAST test), which is a reliability test performed under high temperature and high humidity conditions (for example, 130° C., 85% relative humidity) to accelerate corrosion of inner portion (especially metal portion) of an electronic component. The HAST test includes that performed under conditions with no bias voltage applied to the electronic component tested (unbiased HAST test) and that performed under conditions with a bias voltage applied (biased HAST test). When an Electronic component manufactured with a conventional liquid epoxy resin composition as a mold underfill material for TSV is subjected to a reliability test, particularly the biased HAST test, short-circuiting tends to occur in a short period of time.

In order to solve the above-mentioned problems in the art, an object of the present invention is to provide a liquid epoxy resin composition suitable for use as a mold underfill material for TSV, which composition may provide an electronic component having high wiring density, satisfactorily releasing heat generated during its driving and having high reliability.

As a result of intensive studies to solve the above-mentioned problems, the present inventors have arrived at the present invention.

That is, the present invention includes, but is not limited to, the following inventions.

1. A liquid epoxy resin composition for use as a mold underfill material for TSV, comprising the following (A) to (D):
(A) an epoxy resin;
(B) a curing agent;
(C) an inorganic filler consisting of a silica filler and an alumina filler; and
(D) carbon black, wherein
the epoxy resin (A) comprises an aliphatic epoxy resin represented by formula (I) below:

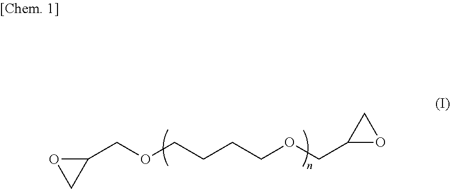

wherein n is an integer of 1 to 15,
the average particle size of the alumina filler is 0.1 μm to 0.3 μm,
the content of the carbon black (D) is 0.1 part by mass or more and 1.5 parts by mass or less, based on the mass of the epoxy resin (A) taken as 100 parts by mass, and
the liquid epoxy resin composition gives a cured product having a thermal conductivity of 0.8 W/m·K or more and less than 1.2 W/m·K.

2. The liquid epoxy resin composition according to item 1 above, wherein
the liquid epoxy resin composition further comprises an ion trapping agent (E), and
the content of chloride ions (Cl⁻) is 0.01 ppm or more and less than 2.5 ppm, based on the total mass of the liquid epoxy resin composition, as measured by a process comprising subjecting to ion chromatography an extract obtained by immersing a cured product of the liquid epoxy resin composition crushed into pieces of 5 mm-square in water at a concentration of 0.1 g/cm³, a temperature of 121° C., a humidity of 100%, and 2 atm for 20 hours.

3. The liquid epoxy resin composition according to item 2 above, wherein the ion trapping agent (E) comprises at least one member selected from bismuth compounds, zirconium compounds, and antimony compounds.

4. The liquid epoxy resin composition according to item 2 above, wherein the average particle size of the ion trapping agent (E) is 0.01 μm to 2 μm.

5. The liquid epoxy resin composition according to item 1 above, wherein
the total chlorine content in the aliphatic epoxy resin represented by formula (I) is 3000 ppm or less, and
the epoxy resin (A) comprises the aliphatic epoxy resin represented by formula (I) in combination with another epoxy resin having a total chlorine content of 3000 ppm or less.

6. The liquid epoxy resin composition according to item 1 above, wherein the content of the inorganic filler (C) is 50 to 90 parts by mass, based on the total mass of the liquid epoxy resin composition taken as 100 parts by mass.

7. The liquid epoxy resin composition according to item 1 above, wherein the epoxy resin (A) further comprises an epoxy resin having an aromatic ring in the molecule.

8. The liquid epoxy resin composition according to item 1 above, wherein the curing agent (B) comprises at least one member selected from the group consisting of phenol compounds and nitrogen-containing heterocyclic compounds.

9. The liquid epoxy resin composition according to item 1 above, further comprising a silicone additive (F).

10. The liquid epoxy resin composition according to item 1 above, further comprising a coupling agent (G).

11. The liquid epoxy resin composition according to item 1 above, wherein the content of particles of the inorganic filler (C) having a particle size of more than 1 μm is less than 1.0 part by mass, based on the total mass of the inorganic filler (C) taken as 100 parts by mass.

12. The liquid epoxy resin composition according to item 1 above, wherein the alumina filler is surface-treated with a silane coupling agent having a methacryloxy group or a phenylamino group.

13. A semiconductor package comprising a semiconductor device encapsulated with the liquid epoxy resin composition of item 1 above.

The liquid epoxy resin composition of the present invention gives a cured product having high thermal conductivity. Thus, an electronic component manufactured using the liquid epoxy resin composition of the present invention as a mold underfill material for TSV satisfactorily releases heat generated during the driving of the component, even when the chip to wafer distance and/or chip to chip distance is/are short. In a semiconductor device including such electronic components, deterioration of performance due to heat is suppressed. Furthermore, in an electronic component that includes a cured product obtained by curing the liquid epoxy resin composition of the present invention, short circuiting does not occur over a long period of time in a biased HAST test. Thus, an electronic component manufactured using the liquid epoxy resin composition of the present invention as a mold underfill material for TSV exhibits satisfactory reliability, even when the bump to bump distance is short. Thus, the liquid epoxy resin composition of the present invention is highly suitable for use as a mold underfill material for TSV.

### BRIEF DESCRIPTION OF THE DRAWINGS

FIGS. 1A, 1B, and 1C are diagrams illustrating a procedure of sealing and overmolding with a mold underfill material for TSV;

FIGS. 2A and 2B are a set of schematic views illustrating locations of a silicon wafer, silicon chips and spacers used for evaluating the injectability of a mold underfill material for TSV, wherein FIG. 2A is a schematic view illustrating locations of the silicon chips arranged on the silicon wafer, FIG. 2B is a schematic view illustrating locations of the silicon chips and spacers on the silicon wafer, and FIG. 2B includes an enlarged view of area IIB in FIG. 2A;

FIGS. 3A and 3B are a set of photomicrographs illustrating the results of evaluation of the injectability of a mold underfill material for TSV, wherein FIG. 3A is a photomicrograph of a polished surface of a test piece prepared from a mold underfill material for TSV with unsatisfactory injectability and FIG. 3B is a photomicrograph of a polished surface of a test piece prepared from a mold underfill material for TSV with good injectability; and

FIG. 4 is a schematic view illustrating the shape of comb-shaped electrodes used in a biased HAST test.

### DETAILED DESCRIPTION OF THE INVENTION

Embodiments of the present invention will be described in detail hereinbelow.

The present invention relates to a liquid epoxy resin composition for use as a mold underfill material for TSV, comprising the following (A) to (D):
(A) an epoxy resin;
(B) a curing agent;
(C) an inorganic filler consisting of a silica filler and an alumina filler; and
(D) carbon black. In the composition, the epoxy resin (A) comprises an aliphatic epoxy resin represented by formula (I) below:

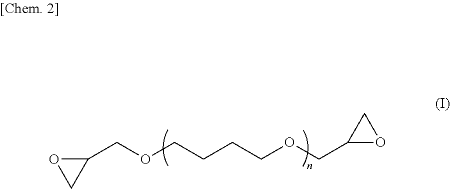

wherein n is an integer of 1 to 15. The average particle size of the alumina filler is 0.1 μm to 0.3 μm. The content of the carbon black (D) is 0.1 part by mass or more and 1.5 parts by mass or less, based on the mass of the epoxy resin (A) taken as 100 parts by mass. The liquid epoxy resin composition gives a cured product having a thermal conductivity of 0.8 W/m·K or more and less than 1.2 W/m·K. The components (A) to (D) contained in the liquid epoxy resin composition of the present invention will be described below.

### Epoxy Resin (A)

The liquid epoxy resin composition of the present invention contains an epoxy resin. As the epoxy resin, it is preferred to use an epoxy resin which is in a liquid form at room temperature. Furthermore, it is preferable to use a liquid epoxy resin having a viscosity in the range of 10 to 5000 mPa·s. By using a liquid epoxy resin, it becomes possible to obtain the liquid epoxy resin composition which exhibits low viscosity and excellent fluidity and is suitable for use as a mold underfill material for TSV.

In the liquid epoxy resin composition of the present invention, the content of the epoxy resin is preferably 10 to 35 parts by mass, more preferably 12 to 32 parts by mass, and particularly preferably 15 to 30 parts by mass, based on the total mass of the liquid epoxy resin composition taken as 100 parts by mass. By the content within this range, it becomes possible to suppress the increase in the viscosity of the liquid epoxy resin composition and lower the coefficient of thermal expansion of a cured product of the liquid epoxy resin composition.

The epoxy resin comprises an aliphatic epoxy resin (diglycidyl ether of (poly)tetramethylene glycol) represented by formula (I) below:

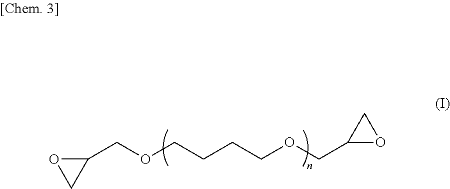

wherein n is an integer of 1 to 15. The letter n in this aliphatic epoxy resin may be calculated from the molecular weight of the epoxy resin (number average molecular weight in terms of that of the standard polystyrene measured by gel permeation chromatography (GPC) using tetrahydrofuran as the elution solvent). The incorporation of this aliphatic epoxy resin may suppress occurrence of warpage after the curing of the liquid epoxy resin composition applied to a wafer having mounted thereon semiconductor chips.

As the aliphatic epoxy resin represented by formula (I) above, a commercially available product, such as “YX7400N” (trade name, manufactured by Mitsubishi Chemical Corporation) or “EPOGOSEY PT (general grade)” (trade name, manufactured by Yokkaichi Chemical Co., Ltd.), may be used.

In the liquid epoxy resin composition of the present invention, the epoxy resin may comprise another epoxy resin in addition to the aliphatic epoxy resin represented by formula (I). An epoxy resin used as a sealing material may be used as another epoxy resin. This epoxy resin is preferably a polyfunctional epoxy resin which is bifunctional or more. Examples of the polyfunctional epoxy resins include:
monocyclic aromatic epoxy resins, such as catechol diglycidyl ether, resorcin diglycidyl ether, phthalic acid diglycidyl ester, 2,5-diisopropylhydroquinone diglycidyl ether and hydroquinone diglycidyl ether;
alicyclic epoxy resins, such as 3′,4′-epoxycyclohexylmethyl-3,4-epoxycyclohexane carboxylate, 3,4-epoxy-6-methylcyclohexylmethyl-3,4-epoxy-6-methylcyclohexyl carboxylate, bis(3,4-epoxycyclohexyl) adipate, vinylcyclohexene monoepoxide and diepoxylimonene;
bisphenol-type epoxy resins, such as bisphenol A type, bisphenol F type, bisphenol AD type and bisphenol S type;
a mixture of oligomers obtained by partial polymerization of a bisphenol-type epoxy resin;
bisphenol-type epoxy resins with hydrogenated ring(s);
tetramethylbis(4-hydroxyphenyl)methane diglycidyl ether;
tetramethylbis(4-hydroxyphenyl)ether diglycidyl ether;
fluorene-type epoxy resins, such as bisphenol fluorene-type epoxy resins and biscresol-type fluorene epoxy resins; and
naphthalene-type epoxy resins.

Further examples of the polyfunctional epoxy resins include:
polyfunctional glycidylamine-type epoxy resins, such as aminophenol-type epoxy resins (such as triglycidyl-p-aminophenol), aniline-type epoxy resins (such as diglycidylaniline), toluidine-type epoxy resins (such as diglycidyl-o-toluidine) and diaminodiphenylmethane-type epoxy resins (such as tetraglycidyldiaminodiphenylmethane);
dicyclopentadiene-type epoxy resins; and
polyfunctional glycidyl ethers, such as trimethylolalkane-type epoxy resins (such as trimethylolpropane triglycidyl ether, trimethylolmethane triglycidyl ether and trimethylolethane triglycidyl ether).

In addition, in combination with them, other epoxy resins, such as aliphatic epoxy resins, silylated epoxy resins, heterocyclic epoxy resins, diallyl bisphenol A-type epoxy resins, and polyarylene ether diglycidyl ethers, may be used.

In the liquid epoxy resin composition of the present invention, these epoxy resins may be used individually or in combination.

The above-mentioned another epoxy resin is preferably an epoxy resin having an aromatic ring in the molecule. In an embodiment of the present invention, the epoxy resin (A) comprises, in addition to the aliphatic epoxy resin represented by formula (I), an epoxy resin having an aromatic ring in the molecule. By the use of an epoxy resin having an aromatic ring in the molecule, curability of the liquid epoxy resin composition is improved, and improved heat resistance brings good results of a biased HAST test.

The mass ratio of the aliphatic epoxy resin represented by formula (I) to the epoxy resin having an aromatic ring is preferably 5:95 to 50:50, more preferably 10:90 to 45:55, and particularly preferably 20:80 to 40:60. By the above-mentioned mass ratio within this range, it becomes possible to suppress occurrence of warpage after the curing of the liquid epoxy resin composition applied to a wafer having mounted thereon semiconductor chips and obtain good results of a biased HAST test.

There is no particular limitation with respect to the epoxy compound having an aromatic ring in the molecule and any conventionally known or commonly used aromatic epoxy compound may be used.

Specific examples of the epoxy compounds having an aromatic ring in the molecule include:
glycidyl ethers of phenols (such as bisphenol A, bisphenol F, bisphenol AD, bisphenol S, catechol and resorcinol);
glycidyl ether esters of hydroxycarboxylic acids (such as p-hydroxybenzoic acid);
monoglycidyl esters or polyglycidyl esters of carboxylic acids (such as benzoic acid, phthalic acid and terephthalic acid);
glycidylamine-type epoxy compounds, such as diglycidylaniline, diglycidyltoluidine, triglycidyl-p-aminophenol and tetraglycidyl-m-xylylenediamine; and
epoxy compounds with a naphthalene skeleton, such as glycidyl ester of naphthol and glycidyl ether ester of β-hydroxynaphthoic acid or the like. Among these, glycidylamine-type epoxy compounds are preferable.

In the present invention, the epoxy resins (A) may contain an epoxy resin which is solid at room temperature, for example, a biphenyl-type epoxy resin and/or a novolak-type epoxy resin (including analogues thereof), as long as the liquid epoxy resin composition of the present invention is liquid at room temperature.

From the point of view of reliability, as will be described later, it is preferable that the content of chloride ions (Cl⁻) in the liquid epoxy resin composition of the present invention be low. It is therefore preferable that the epoxy resin included in the epoxy resin (A) has a low content of chloride ions. The total chlorine content in the epoxy resin(s) contained in the epoxy resin (A) is preferably 3000 ppm or less, more preferably 2500 ppm or less, and particularly preferably 1500 ppm or less. This applies also to the aliphatic epoxy resin represented by formula (I) and another epoxy resin. In an embodiment, the total chlorine content in the aliphatic epoxy resin represented by formula (I) is 3000 ppm or less, and the epoxy resin (A) comprises the aliphatic epoxy resin represented by formula (I) in combination with another epoxy resin having a total chlorine content of 3000 ppm or less.

### Curing Agent (B)

The liquid epoxy resin composition of the present invention contains a curing agent. The curing agent is not particularly limited as long as the epoxy resin (A) can be cured. Examples of the curing agents which may be used in the liquid epoxy resin composition of the present invention include phenol compounds, acid anhydrides, amine compounds (in particular, non-cyclic amine compounds), nitrogen-containing heterocyclic compounds (in particular, imidazole compounds) and organometallic compounds. In an embodiment, among these, basic one is used.

Examples of the above-mentioned phenol compounds which may be preferably used include phenol resins, particularly a novolak resin obtained by condensing a phenol or a naphthol (such as phenol, cresol, naphthol, an alkylphenol, a bisphenol and a terpene phenol) with formaldehyde. Examples of the novolak resins include a phenol novolak resin, an o-cresol novolak resin, a p-cresol novolak resin, an α-naphthol novolak resin, a β-naphthol novolak resin, a t-butylphenol novolak resin, a bisphenol A-type novolak resin, a xylylene-modified novolak resin, a decalin-modified novolak resin and the like. Further examples of the phenol resins include a dicyclopentadiene cresol resin, a poly-p-vinylphenol, a poly(di-o-hydroxyphenyl)methane, a poly(di-m-hydroxyphenyl)methane, a poly(di-p-hydroxyphenyl)methane and the like.

Examples of the above-mentioned acid anhydrides include phthalic anhydride; hexahydrophthalic anhydride; an alkylhexahydrophthalic anhydrides, such as methylhexahydrophthalic anhydride; tetrahydrophthalic anhydride; an alkyltetrahydrophthalic anhydrides, such as a trialkyltetrahydrophthalic anhydrides and 3-methyltetrahydrophthalic anhydride; himic anhydride; succinic anhydride; trimellitic anhydride; and pyromellitic anhydride. Among these, preferred are methyltetrahydrophthalic anhydride, methylhexahydrophthalic anhydride and the like.

Examples of the above-mentioned (non-cyclic) amine compounds include 2,4,6-tris(dimethylaminomethyl)phenol, diethylamine, triethylamine, diethylenetetramine, triethylenetetramine, tetramethyldiaminodiphenylmethane, tetraethyldiaminodiphenylmethane, diethyldimethyldiaminodiphenylmethane, dimethyldiaminotoluene, diaminodibutyltoluene, diaminodipropyltoluene, diaminodiphenylsulfone, diaminoditolylsulfone, diethyldiaminotoluene, bis(4-amino-3-ethylphenyl)methane, polytetramethylene oxide-di-p-aminobenzoate, 4,4-dimethylaminopyridine and the like. The amine compounds may be amine adducts.

Examples of the nitrogen-containing heterocyclic compounds include imidazoles, such as 2-methylimidazole, 2-undecylimidazole, 2-heptadecylimidazole, 2-ethyl-4-methylimidazole, 2-phenylimidazole, 2-phenyl-4-methylimidazole, 2,4-diamino-6-[2′-methylimidazolyl-(1′)]ethyl-s-triazine, 2-phenyl-4,5-dihydroxymethylimidazole, 2-phenyl-4-methyl-5-hydroxymethylimidazole, and 2,3-dihydro-1H-pyrrolo[1,2-a]benzimidazole; diazabicycloundecene (DBU), DBU-phenol salt, DBU-octylate salt, DBU-p-toluenesulfonate salt, DBU-formate salt, DBU-o-phthalate salt, DBU-phenol novolak resin salt, DBU tetraphenylborate salt, diazabicyclononene (DBN), DBN-phenol novolak resin salt, diazabicyclooctane, pyrazole, oxazole, thiazole, imidazoline, pyrazine, morpholine, thiazine, indole, isoindole, benzimidazole, purine, quinoline, isoquinoline, quinoxaline, cinnoline, pteridine and the like. The nitrogen-containing heterocyclic compound which forms an adduct with an epoxy resin or isocyanate compound or is microencapsulated may be used.

Examples of the above-mentioned organometallic compounds include zinc naphthenate, cobalt naphthenate, tin octylate, cobalt octylate, bisacetylacetonatocobalt (II), trisacetylacetonatocobalt (III) and the like.

In the present invention, the curing agent preferably comprises at least one member selected from the group consisting of phenol compounds, acid anhydrides, non-cyclic amine compounds and nitrogen-containing heterocyclic compounds, more preferably comprises at least one member selected from the group consisting of phenol compounds and nitrogen-containing heterocyclic compounds, and still more preferably comprises a nitrogen-containing heterocyclic compound. The nitrogen-containing heterocyclic compound may be latent. A microencapsulated latent curing agent may be used.

Particularly preferably, the nitrogen-containing heterocyclic compound is an imidazole compound. Examples of the imidazole compounds include imidazole; 2-substituted imidazole compounds, such as 2-methylimidazole, 2-ethylimidazole, 1-isobutyl-2-methylimidazole, 2-ethyl-4-methylimidazole, 2-phenylimidazole, 2-phenyl-4-methylimidazole, 1-benzyl-2-methylimidazole, 1-benzyl-2-phenylimidazole, 1,2-dimethylimidazole, 1-cyanoethyl-2-methylimidazole, 1-cyanoethyl-2-ethyl-4-methylimidazole, 1-cyanoethyl-2-undecylimidazole, and 1-cyanoethyl-2-phenylimidazole; trimellitate salts, such as 1-cyanoethyl-2-undecylimidazolium trimellitate and 1-cyanoethyl-2-phenylimidazolium trimellitate; triazine compounds, such as 2,4-diamino-6-[2′-methylimidazolyl-(1′)]-ethyl-s-triazine, 2,4-diamino-6-[2′-undecylimidazolyl-(1′)]-ethyl-s-triazine, and 2,4-diamino-6-[2′-ethyl-4′-methylimidazolyl-(1′)]-ethyl-s-triazine; adduct of 2,4-diamino-6-[2′-methylimidazolyl-(1′)]-ethyl-s-triazine with isocyanuric acid, adduct of 2-phenylimidazole with isocyanuric acid, adduct of 2-methylimidazole with isocyanuric acid, adduct of 2-phenyl-4,5-dihydroxymethylimidazole with isocyanuric acid, adduct of 2-phenyl-4-methyl-5-dihydroxymethylimidazole with isocyanuric acid and the like.

As the above-mentioned microencapsulated curing agent, for example, a dispersion comprising a liquid epoxy resin having dispersed therein a powder of an amine compound (including a nitrogen-containing heterocyclic compound) may be used. The amine compound may be appropriately selected from, for example, aliphatic primary amines, alicyclic primary amines, aromatic primary amines, aliphatic secondary amines, alicyclic secondary amines, aromatic secondary amines, imidazole compounds and imidazoline compounds. The amine compounds may be used in the form of reaction products with, for example, carboxylic acids, sulfonic acids, isocyanates and epoxides. These compounds may be used individually or in combination. For example, the amine compound may be used in combination with a reaction product thereof with a carboxylic acid, a sulfonic acid, an isocyanate or an epoxide. The volume average particle size of the powder of the amine compound is preferably 50 μm or less, and more preferably 10 μm or less. From the viewpoint of suppression of increase in viscosity at 25° C., the powder of the amine compound preferably has a melting point or softening point of 60° C. or more.

In the liquid epoxy resin composition of the present invention, the curing agents may be used individually or in combination. In the present invention, the curing agent is preferably an imidazole compound, and more preferably a combination of an imidazole compound and a phenol compound. The combined use of an imidazole compound and a phenol compound offers increased curability while improving the storage stability.

In the liquid epoxy resin composition of the present invention, the content of the curing agent is preferably 1 to 20 mass %, more preferably 2 to 17 mass %, and particularly preferably 3 to 15 mass % relative to the epoxy resin (A). By this range, curing time of the liquid epoxy resin composition does not become too long, productivity of electronic components with highly densified wiring formed by TSV or other technique is improved, occurrence of warpage after the curing of the liquid epoxy resin composition applied to a wafer having mounted thereon semiconductor is suppressed and storage stability of the liquid epoxy resin composition is improved.

### Inorganic Filler (C)

The liquid epoxy resin composition of the present invention contains an inorganic filler. The inorganic filler consists of a silica filler and an alumina filler.

The liquid epoxy resin composition of the present invention, which contains an alumina filler having high thermal conductivity, gives a cured product with high thermal conductivity. Thus, in an electronic component manufactured using the liquid epoxy resin composition of the present invention as a mold underfill material for TSV, heat generated during the driving of the component is easily released. This contributes to further improvement in performance of an electronic component.

The alumina filler contains an alumina powder. The alumina powder is commercially available. The shape of the particles of the alumina filler is not particularly limited, and the particles may be in any shape, such as spherical, amorphous, or scale. From the viewpoint of the fluidity of the liquid epoxy resin composition used as a mold underfill material for TSV, it is particularly preferred that the particles of the alumina filler are spherical. Such an alumina filler, which is capable of being highly filled, is preferred also from the viewpoint of improvement of thermal conductivity of the cured product.

The alumina filler may be surface-treated with a surface-treating agent, for example, a silane coupling agent (which may have a substituent, such as a phenyl group, a vinyl group a methacryloyl group or the like). The use of a surface-treated alumina filler lowers the viscosity of the liquid epoxy resin composition and improves the injectability. The term “injectability” means the degree of ease for the liquid epoxy resin composition to fill between a wafer and a chip and between chips at the time of compression molding.

From the viewpoint of injectability the time of application of the liquid epoxy resin composition as a mold underfill material for TSV and reduction of warpage of the cured product, it is particularly preferable to use an alumina filler surface-treated with a silane coupling agent having a methacryloxy group or a phenylamino group. In an embodiment, the alumina filler is surface-treated with a silane coupling agent having a methacryloxy group or a phenylamino group. Each of such surface-treated alumina fillers improves the above-described properties of the liquid epoxy resin composition. However, usually, the above-mentioned properties are more improved when an alumina filler surface-treated with a silane coupling agent having a methacryloxy group is used, as compared to those when an alumina filler surface-treated with a silane coupling agent having a phenylamino group is used. In an embodiment, the alumina filler is surface-treated with a silane coupling agent having a methacryloxy group.

The average particle size of the alumina filler used in the present invention is 0.1 μm to 0.3 μm, and preferably 0.15 μm to 0.25 μm. If the average particle size is less than 0.1 μm, the viscosity of the liquid epoxy resin composition tends to become high. This results in difficulty in addition of the alumina filler to the liquid epoxy resin composition in an amount necessary for satisfactory improvement of thermal conductivity. On the other hand, if the average particle size of the alumina filler is more than 0.3 μm, the injectability of the liquid epoxy resin composition is lowered.

The average particle size of the alumina filler is obtained as the particle size (D₅₀) at the cumulative volume of 50% of the volume particle size distribution. More specifically, the average particle size and the like can be obtained based on the particle size distribution measured, using a sample arbitrarily extracted from the population, by means of a laser diffraction scattering type particle size distribution measurement apparatus.

Addition of an alumina filler to a sealant/encapsulant for the production of an electronic component for improvement of the thermal conductivity and the like has been conventionally known (see Patent Literatures 2 and 3). However, the usefulness of the addition of an alumina filler to a liquid epoxy resin composition used as a mold underfill material for TSV and the properties of the alumina filler suitable for such an application have been found first by the present inventors.

In the liquid epoxy resin composition of the present invention, the content of the alumina filler is preferably 40 to 80 parts by mass, more preferably 45 to 78 parts by mass, and particularly preferably 50 to 75 parts by mass, based on the total mass of the liquid epoxy resin composition taken as 100 parts by mass.

The liquid epoxy resin composition of the present invention, which contains a silica filler together with the alumina filler, gives a cured product with a lowered coefficient of linear thermal expansion.

The silica filler comprises a silica powder. The silica powder is commercially available. The silica may be natural silica (such as silica stone and quartz) or synthetic silica. The synthetic silica may be synthesized by any methods including dry process and wet process.

Preferably, a fused silica powder is used as the silica filler. Examples of the fused silica powders include spherical fused silica powder, crushed fused silica powder and the like. From the viewpoint of the fluidity of the liquid epoxy resin composition, it is more preferable to use a spherical fused silica powder (in particular, one composed of particles with high sphericity) as the silica filler.

The silica filler may be surface-treated with a surface-treating agent, for example, a silane coupling agent (which may have a substituent, such as an epoxy group, an amino group, a phenyl group, a vinyl group, a (meth)acryloyl group and the like). By the use of a surface-treated silica filler, the viscosity of the liquid epoxy resin composition is lowered and the injectability can be improved.

The average particle size of the silica filler used in the present invention is preferably 5 nm to 100 nm, and more preferably 10 nm to 50 nm. If the average particle size of the silica filler is out of the range of 5 nm to 100 nm, the liquid epoxy resin composition may exhibit inappropriate viscosity and/or injectability. The average particle size of the silica filler can be obtained by analyzing a photomicrograph (for example, an electron photomicrograph) of a sample of the component (C) with an image processing software to quantify and statistically process the size of all or part of the particles in the photomicrograph.

In the liquid epoxy resin composition of the present invention, the content of the silica filler is preferably 5 to 23 parts by mass, and more preferably 8 to 19 parts by mass, based on the total mass of the liquid epoxy resin composition taken as 100 parts by mass.

The inorganic filler (C) used in the present invention consists of the silica filler and the alumina filler and contains no other fillers. It is not preferred that the inorganic filler (C) contains another filler since the liquid epoxy resin composition cannot be highly filled with the filler and thermal conductivity and fluidity are disadvantageously lowered. This is caused by the sphericity of another filler lower than that of the silica filler and alumina filler.

In the liquid epoxy resin composition of the present invention, the content of the inorganic filler (C) is preferably 50 to 90 parts by mass, more preferably 55 to 88 parts by mass, and particularly preferably 60 to 85 parts by mass, based on the total mass of the liquid epoxy resin composition taken as 100 parts by mass. The mass ratio of the silica filler to the alumina filler is preferably 40:60 to 1:99, more preferably 30:70 to 5:95, and particularly preferably 20:80 to 10:90.

By the above-mentioned addition of the inorganic filler (C), the liquid epoxy resin composition of the present invention gives a cured product with improved thermal conductivity. Specifically, the liquid epoxy resin composition of the present invention gives a cured product having a thermal conductivity of 0.8 W/m·K or more and less than 1.2 W/m·K. If the thermal conductivity of a cured product given by the liquid epoxy resin composition of the present invention is less than 0.8 W/m·K, heat generated during the driving of an electronic component containing the cured product is not satisfactory released. The thermal conductivity of a cured product is preferably 0.7 W/m·K or more, more preferably 0.75 W/m·K or more, and particularly preferably 0.8 W/m·K or more. On the other hand, the thermal conductivity of the cured product is less than 1.2 W/m·K, because of the presence of other components, despite the improvement by the alumina filler.

Furthermore, a cured product of the liquid epoxy resin composition of the present invention has a low coefficient of linear thermal expansion by virtue of the addition of the inorganic filler (C).

In an electronic component having a plurality of three-dimensionally stacked chips, the chip to wafer distance and/or chip to chip distance is/are becoming short with the above-mentioned densification of wiring. In such an electronic component, release of heat generated during its driving becomes difficult and the performance of a semiconductor device having such electronic components may be deteriorated by the heat. In a semiconductor device having electronic components manufactured with a mold underfill material containing a silica filler having low thermal conductivity, this release of heat becomes more difficult.

In contrast, a cured product given by the liquid epoxy resin composition of the present invention has a thermal conductivity higher than that of a cured product given by a conventional mold underfill material for TSV. Thus, an electronic component manufactured using the liquid epoxy resin composition of the present invention as a mold underfill material for TSV achieves satisfactory release of heat generated during the driving of the electronic component, even when the chip to wafer distance and/or chip to chip distance is/are short. In a semiconductor device having such electronic components, deterioration of performance by heat is suppressed.

In the present invention, from the viewpoint of injectability, it is particularly preferable that the content of particles of the inorganic filler (C) having a particle size of more than 1 μm be less than 1.0 part by mass, based on the total mass of the inorganic filler (C) taken as 100 parts by mass. The liquid epoxy resin composition of the present invention may further comprise a silica filler and/or an alumina filler having an average particle size of less than 0.1 μm as an optional component, as long as the properties of the composition are not adversely affected.

### Carbon Black (D)

The liquid epoxy resin composition of the present invention contains carbon black. Considering the possibility that wiring in an electronic component is affected by light, the use of carbon black is important. The carbon black is not particularly limited and may be appropriately selected and employed from carbon blacks usually contained in epoxy resin compositions. Examples of such carbon blacks include acetylene black, furnace black, Ketjen black, channel black, lamp black, thermal black and the like. These may be used individually or in combination.

In the present invention, the carbon black may be used in combination with another black pigment. Black organic pigments, mixed-color organic pigments, black inorganic pigments and the like may be used as the other black pigments. Examples of the black organic pigments include perylene black and aniline black. Examples of the mixed-color organic pigments include those obtained by mixing at least two kinds of pigments selected from red, blue, green, purple, yellow, magenta, cyan and the like to obtain a pseudo-black color. Examples of the black inorganic pigments include graphite, metals and oxides (including complex oxides), sulfides, nitrides and the like of the metals. Examples of the metals include titanium, copper, iron, manganese, cobalt, chromium, nickel, zinc, calcium, silver and the like.

The carbon black may be used in combination with other colorants, such as dyes.

In the liquid epoxy resin composition of the present invention, the content of the carbon black is 0.1 part by mass or more and 1.5 parts by mass or less, based on the mass of the epoxy resin (A) taken as 100 parts by mass. The content of the carbon black is preferably 0.1 part by mass or more and 1.3 parts by mass or less, and more preferably 0.1 part by mass or more and 1.1 parts by mass or less. The content of the carbon black is preferably 0.01 part by mass or more and 0.60 parts by mass or less, more preferably 0.01 part by mass or more and 0.45 parts by mass or less, and still more preferably 0.01 part by mass or more and 0.30 parts by mass or less, based on the total mass of the liquid epoxy resin composition taken as 100 parts by mass.

If the content of the carbon black is below the above range, light may be unsatisfactorily shielded and adversely affect wiring in an electronic component. If the content of the carbon black exceeds the above range, an electronic component obtained by packaging, with the liquid epoxy resin composition, of a plurality of chips stacked using TSV technique tends to cause short-circuiting in a biased HAST test. That is, the reliability of such electronic components is lowered.

If desired, the liquid epoxy resin composition of the present invention may contain optional components, such as those described below, in addition to the essential components (A) to (D).

### Ion Trapping Agent (E)

If desired, the liquid epoxy resin composition of the present invention may contain an ion trapping agent. In an embodiment, the liquid epoxy resin composition of the present invention further comprises an ion trapping agent. An ion trapping agent is a compound which traps ionic impurities contained in a resin, such as the epoxy resin (A). By the ion trapping agent contained, anionic impurities present in the liquid epoxy resin composition, such as chloride ions (Cl⁻) are trapped, and short-circuit failure during the driving is suppressed.

The ion trapping agents include cation trapping agents and anion trapping agents. The ion trapping agent used in the present invention is not particularly limited and may be an inorganic compound or an organic compound as long as the agent can trap chloride ions. Examples of the organic compounds used as the ion trapping agents include triazole compounds, tetrazole compounds, bipyridyl compounds and the like. Examples of the inorganic compounds for use as the ion trapping agents include rare earth oxides; bismuth compounds, such as bismuth hydroxide compounds; antimony compounds; titanium compounds; zirconium compounds having specific structures, such as zirconium phosphate; magnesium compounds, such as hydrotalcites; and aluminum compounds. From the viewpoint of higher trapping effect for chloride ions, the ion trapping agent preferably comprises, among these, at least one member selected from bismuth compounds, zirconium compounds and antimony compounds, and more preferably consists solely of any of these compounds. The ion trapping agents may be used individually or in combination.

In the liquid epoxy resin composition of the present invention, the content of the ion trapping agent is preferably 0.5 to 6 parts by mass, more preferably 0.7 to 5 parts by mass, and particularly preferably 1 to 4 parts by mass, with respect to 100 parts by mass of the epoxy resin (A). By the content within this range, chloride ion concentration in the liquid epoxy resin composition is satisfactorily lowered with no inhibition of properties required for use as a mold underfill material for TSV. If the content of the ion trapping agent is less than 0.5 parts by mass, failure in effective trapping of chloride ions may result in short-circuiting in a biased HAST test.

The average particle size of the ion trapping agent used in the present invention is preferably 0.01 μm (10 nm) to 2 μm, more preferably 0.1 μm to 2.0 μm, and still more preferably 0.2 μm to 1.5 μm. The average particle size of the ion trapping agent can be obtained in substantially the same manner as in the average particle size of the alumina filler.

The upper limit of the average particle size of the ion trapping agent is preferably 2.0 μm, more preferably 1.8 μm, still more preferably 1.5 μm, even more preferably 1.2 μm, further preferably 1.0 μm, still further preferably 0.8 μm, even further preferably 0.5 μm, and particularly preferably 0.4 μm, considering the chip to wafer distance and/or chip to chip distance in an electronic component containing a plurality of three-dimensionally stacked chips, and the bump to bump distance in an electronic component having a plurality of bumps. The lower limit of the average particle size of the ion trapping agent is not particularly limited as long as the liquid epoxy resin composition having appropriate handleability and capable of being injected into narrow space in an electronic component is obtained, but is preferably 0.01 μm (10 nm), more preferably 0.1 μm, and still more preferably 0.2 μm.

The ion trapping agent may be a commercially available product. Examples thereof include IXE series manufactured by TOAGOSEI CO., LTD. and IXEPLAS series manufactured by TOAGOSEI CO., LTD.

Addition of an ion trapping agent to an encapsulant for manufacturing an electronic component has been conventionally known (see Patent Literatures 1 and 4). However, the usefulness of the addition of an ion trapping agent to a liquid epoxy resin composition used as a mold underfill material for TSV and properties of the ion trapping agent suitable for such an application have been found first by the present inventors.

### Silicone Additive (F)

If desired, the liquid epoxy resin composition of the present invention may contain a silicone additive. In an embodiment, the liquid epoxy resin composition of the present invention further comprises a silicone additive. It is preferred from the viewpoint of improvement of the fluidity of the liquid epoxy resin composition that the silicone additive is contained. It is preferred that the silicone additive is a dialkylpolysiloxane (examples of the alkyl groups bonded to Si include methyl, ethyl and the like), particularly a dimethylpolysiloxane. The silicone additive may be a modified dialkylpolysiloxane, for example, an epoxy-modified dimethylpolysiloxane. Specific examples of the silicone additives include KF69 (dimethylsilicone oil, manufactured by Shin-Etsu Silicone Co., Ltd.) SF8421 (epoxy-modified silicone oil, manufactured by Dow Toray Silicone) and the like. The silicone additives may be used individually or in combination.

When the liquid epoxy resin composition of the present invention contains the silicone additive, the amount of the silicone additive is preferably 0.1 to 1.0 part by mass, and more preferably 0.25 to 1 part by mass with respect to 100 parts by mass of the epoxy resin (A).

### Coupling Agent (G)

If desired, the liquid epoxy resin composition of the present invention may contain a coupling agent. In an embodiment, the liquid epoxy resin composition of the present invention further comprises a coupling agent. It is preferred from the viewpoint of improvement of the adhesion strength that a coupling agent, in particular a silane coupling agent is contained. Various silane coupling agents, such as epoxy-based, amino-based, vinyl-based, methacrylic-based, acrylic-based and mercapto-based silane coupling agents, may be used as the coupling agent. Specific examples of the silane coupling agents include 3-glycidoxypropyltrimethoxysilane, 3-aminopropyltrimethoxysilane, vinyltrimethoxysilane, 3-triethoxysilyl-N-(1,3-dimethyl-butylidene)propylamine, 2-(3,4-epoxycyclohexyl)ethyltrimethoxysilane, p-styryltrimethoxysilane, 3-methacryloxypropylmethyltrimethoxysilane, 3-acryloxypropyltrimethoxysilane, 8-glycidoxyoctyltrimethoxysilane, 3-ureidopropyltriethoxysilane, 3-mercaptopropyltrimethoxysilane, bis(triethoxysilylpropyl)tetrasulfide, 3-isocyanatopropyltriethoxysilane and the like. The silane coupling agents may be used individually or in combination.

When the liquid epoxy resin composition of the present invention contains the coupling agent, the amount of the coupling agent is preferably 0.01 to 5 parts by mass, and more preferably 0.1 to 3 parts by mass with respect to 100 parts by mass of the epoxy resin (A).

### Migration Inhibitor (H)

If desired, the liquid epoxy resin composition of the present invention may contain a migration inhibitor. In an embodiment, the liquid epoxy resin composition of the present invention further comprises a migration inhibitor. Migration is a phenomenon in which the metal of a wiring pattern is dissolved by electrochemical reaction to cause decrease in resistance. It is preferred from the viewpoint of improvement of the reliability of electronic components that the migration inhibitor is contained. Specific examples of the migration inhibitors include xanthines, such as caffeine, theophylline, theobromine and paraxanthine; tocols, such as 5,7,8-trimethyltocol (α-tocopherol), 5,8-dimethyltocol (β-tocopherol), 7,8-dimethyltocol (γ-tocopherol) and 8-methyltocol (δ-tocopherol); tocotrienols, such as 5,7,8-trimethyltocotrienol (α-tocotrienol), 5,8-dimethyltocotrienol (β-tocotrienol), 7,8-dimethyltocotrienol (γ-tocotrienol) and 8-methyltocotrienol (δ-tocotrienol); benzotriazoles, such as benzotriazole, 1H-benzotriazole-1-methanol and alkylbenzotriazoles; triazines, such as 2,4-diamino-6-vinyl-S-triazine, 2,4-diamino-6-[2′-ethyl-4-methylimidazole-(1)]-ethyl-S-triazine and 2,4-diamino-6-methacryloyloxyethyl-S-triazine; isocyanuric acid adducts of the benzotriazoles and triazines as described above, and the like. The migration inhibitors may be used individually or in combination.

When the liquid epoxy resin composition of the present invention contains the migration inhibitor, the amount of the migration inhibitor is preferably 0.01 to 5 parts by mass, and more preferably 0.1 to 3 parts by mass with respect to 100 parts by mass of the epoxy resin (A).

### Stabilizer (I)

If desired, the liquid epoxy resin composition of the present invention may contain a stabilizer. A stabilizer may be contained in the liquid epoxy resin composition of the present invention in order to improve the storage stability of the composition and extend the pot life. Various stabilizers known in the art as stabilizers for one-part epoxy-based adhesives may be used, and at least one selected from the group consisting of liquid boric acid ester compounds, aluminum chelates and organic acids is preferable because of their high effectiveness in storage stability.

Examples of the liquid boric acid ester compounds include 2,2′-oxybis(5,5′-dimethyl-1,3,2-oxaborinane), trimethyl borate, triethyl borate, tri-n-propyl borate, triisopropyl borate, tri-n-butyl borate, tripentyl borate, triallyl borate, trihexyl borate, tricyclohexyl borate, trioctyl borate, trinonyl borate, tridecyl borate, tridodecyl borate, trihexadecyl borate, trioctadecyl borate, tris(2-ethylhexyloxy)borane, bis(1,4,7,10-tetraoxaundecyl)(1,4,7,10,13-pentoxatetradecyl)(1,4,7-trioxaundecyl)borane, tribenzyl borate, triphenyl borate, tri-o-tolyl borate, tri-m-tolyl borate, triethanolamine borate and the like. A liquid boric acid ester compound is preferable, because it is liquid at room temperature (25° C.) and therefore allows the viscosity of the liquid epoxy resin composition to be kept low. As the aluminum chelate, aluminum chelate A may be used, for example. As the organic acid, barbituric acid may be used, for example.

When the liquid epoxy resin composition of the present invention contains the stabilizer, the amount of the stabilizer is preferably 0.01 to 30 parts by mass, more preferably 0.05 to 25 parts by mass, and still more preferably 0.1 to 20 parts by mass with respect to 100 parts by mass of the epoxy resin (A).

### Other Additives (J)

If desired, the liquid epoxy resin composition of the present invention may comprise other additives, such as a leveling agent, an antioxidant, an antifoaming agent, a thixotropic agent, a viscosity modifier, a flame retardant, a reactive diluent, a solvent, an elastomers and the like, insofar as they do not depart from the spirit of the present invention. The types and the amounts of the additives are in accordance with a usual practice in the art.

One or more of the components (including the components (A) to (D)) contained in the liquid epoxy resin composition of the present invention may be present as a microparticulate solid. In the present invention, from the view point of injectability, it is preferred that the content of particles having a particle size of more than 1 μm is less than 1.0 part by mass, based on the total mass of the liquid epoxy resin composition taken as 100 parts by mass.

There is no particular limitation with respect to the method for producing the liquid epoxy resin composition of the present invention. For example, the liquid epoxy resin composition of the present invention may be obtained by introducing the components (A) to (D) and, if desired, other component(s) such as the ion trapping agent (E) into a suitable mixer simultaneously or separately, followed by stirring and mixing while, if necessary, heating and melting, to yield a homogeneous composition. The mixer is not particularly limited, and a Raikai mixer (grinder) equipped with a stirrer and a heater, a Henschel mixer, a three-roll mill, a ball mill, a planetary mixer, a bead mill or the like can be used. These devices may be used in combination, as appropriate.

The liquid epoxy resin composition thus obtained is thermosetting and, under the conditions with the temperature of 100 to 170° C., cures preferably within 0.1 to 3 hours, more preferably in 0.25 to 2 hours.

In the liquid epoxy resin composition of the present invention, the content of chloride ions (Cl⁻) is preferably 0.01 ppm or more and less than 7.0 ppm, more preferably 0.01 ppm or more and less than 5.0 ppm, and still more preferably 0.01 ppm or more and less than 3.0 ppm, based on the total mass of the liquid epoxy resin composition. If the content of chloride ions is 2.5 ppm or more, an electronic component obtained by packaging, with the liquid epoxy resin composition, of a plurality of chips stacked using TSV technique tends to cause short-circuiting in a biased HAST test. That is, the reliability of such electronic components is lowered. On the other hand, the content of chloride ions is preferably 0.01 ppm or more from the viewpoint of commercial availability.

The content of chloride ions can be measured by a method comprising extracting a sample with purified water at a high temperature and a high pressure (for example, 0.1 g/cm³ concentration, 121° C., 100% humidity, 2 atm, 20 hours) and subjecting the resultant extract to ion chromatography. When it is difficult to measure the content of chloride ions in the liquid epoxy resin composition of the present invention, this content is regarded as the same as the content of chloride ions measured by applying the method described above to a cured product (crushed (for example, into pieces of about 5 mm-square) as required) obtained by curing this liquid epoxy resin composition.

As described above, in the of production an electronic component comprising a plurality of stacked chips, conventionally employed were the steps of carrying out, in each stacking of a chip, sealing between a wafer and a chip or between chips; and carrying out overmolding. In such steps, used for sealing was a resin composition having lower content of chloride ions as compared to the resin composition used for overmolding.

On the other hand, when the sealing and overmolding are carried out in one step using a mold underfill material for TSV, the same resin composition must be used in both of the sealing and overmolding. A conventional resin composition for sealing is not suitable as a mold underfill material for TSV for the reasons of moisture resistance, ion-elution resistance and the like. On the other hand, when an electronic component comprising a plurality of stacked chips is produced using a conventional resin composition for overmolding as a mold underfill material for TSV, the resultant electronic component tends to cause short-circuiting in a biased HAST test. That is, such an electronic component has low reliability.

In the liquid epoxy resin composition of the present invention, by the content of the carbon black (D) within the above-described range, reliability of an electronic component comprising a cured product obtained by curing this composition used as a mold underfill material for TSV is improved. However, the content of chloride ions in the composition within the range described above, which results in further improvement of this reliability, is therefore extremely preferred.

The viscosity at 25° C. of the liquid epoxy resin composition of the present invention measured using a rotational viscometer at the number of rotation of 20 rpm is preferably 20 Pa·s to 450 Pa·s, more preferably 40 Pa·s to 400 Pa·s, and particularly preferably 60 Pa·s to 350 Pa·s. By the viscosity at 25° C. within this range, the injectability of the liquid epoxy resin composition is improved.

The thixotropic index (TI) of the liquid epoxy resin composition of the present invention is preferably 0.3 to 5.0, more preferably 0.5 to 4.0, and particularly preferably 1.0 to 3.0. By the TI within this range, the injectability of the liquid epoxy resin composition is improved. TI of the liquid epoxy resin composition is represented by the following formula:

$$TI = {η}_{2} / {η}_{20}$$

(wherein
η₂ is the viscosity of the liquid epoxy resin composition measured using a rotational viscometer under conditions with a temperature of 25° C. and a number of rotation of 2 rpm; and
η₂₀ is the viscosity of the liquid epoxy resin composition measured under the conditions substantially the same as those for η₂, except that the number of rotation is 20 rpm).

The viscosity at 120° C. of the liquid epoxy resin composition of the present invention measured with a rheometer is preferably 1.0 Pa·s to 10 Pa·s, more preferably 1.5 Pa·s to 7 Pa·s, and particularly preferably 2.0 Pa·s to 6 Pa·s. By the viscosity at 120° C. within this range, the injectability of the liquid epoxy resin composition is improved.

The liquid epoxy resin composition of the present invention can be used, for example, as an adhesive or a sealant for fixing, bonding, or protecting parts constituting a semiconductor device, including various electronic components (such as semiconductor elements) and parts constituting the electronic components, or a raw material thereof. The liquid epoxy resin composition of the present invention is suitable as an underfill material for protecting, or fixing to a substrate, electronic components and the like, in particular, a mold underfill material for TSV used in a technique in which sealing between a wafer and a chip and between each pair of chips and molding of the outer shape of the electronic component are carried out in one step. As an example of a process for producing an electronic component by such a technique, a compression molding process is illustrated in FIGS. 1A to 1C. A wafer having mounted thereon a plurality of stacked semiconductor chips (FIG. 1A) is placed into a compression molding machine equipped with a mold, and the mold underfill material for TSV is applied to the wafer (FIG. 1B). The wafer is subjected to compression molding under heating, and subsequently the mold underfill material is cured by heating (FIG. 1C). By such a process, sealing between a wafer and the chips and between each pair of the chips and molding of the outer shape of the electronic component can be achieved in one step.

The liquid epoxy resin composition of the present invention is particularly useful in the production of an electronic component using wafer level chip size packaging technique, the electronic component having a plurality of three-dimensionally stacked with short chip to wafer distance and/or chip to chip distance, and/or the electronic component having bumps with short bump to bump distance.

In an electronic component manufactured using the liquid epoxy resin composition of the present invention, which component contains a three-dimensionally stacked chips, the chip to wafer distance and/or chip to chip distance(s) is/are preferably 40 μm or less, more preferably 30 μm or less, and still more preferably 20 μm or less.

In an electronic component manufactured using the liquid epoxy resin composition of the present invention, which component has a plurality of bumps, the average distance between the bumps is preferably 100 μm or less, more preferably 80 μm or less, and still more preferably 40 μm or less.

In the present invention, also provided is a cured product obtained by curing the liquid epoxy resin composition of the present invention. In the present invention, further provided is an electronic component comprising the cured product of the present invention.

In the present invention, also provided is a semiconductor element sealed with the liquid epoxy resin composition of the present invention. In the present invention, further provided is a semiconductor package having a semiconductor device encapsulated with the liquid epoxy resin composition of the present invention.

### EXAMPLES

Hereinbelow, the present invention will be described by way of Examples without limiting the scope of the present invention to such Examples. In the following description, “part(s)” and “%” indicate part(s) by mass and mass % unless otherwise mentioned.

### Examples 1 to 7, Comparative Example 1 and Reference Examples 1 to 4

Liquid epoxy resin compositions were prepared by mixing each of the components in the predetermined amounts according to the formulations shown in Table 1 using a three-roll mill. In Table 1, the amounts of the components are expressed by parts by mass (unit: g).

### Epoxy Resins (A)

The compounds used as the epoxy resins (A) in Examples, Comparative Example and Reference Examples are as follows.
(A-1): Aliphatic epoxy resin (trade name: YX7400N, manufactured by Mitsubishi Chemical Corporation, total chlorine content: 500 ppm, liquid at room temperature) (diglycidyl ether of polytetramethylene glycol)
(A-2): Glycidylamine-type epoxy resin (trade name: jER630LSD, manufactured by Mitsubishi Chemical Corporation, total chlorine content: 1500 ppm, liquid at room temperature) (epoxy resin having an aromatic ring)
(A-3): Glycidylamine-type epoxy resin (trade name: jER630, manufactured by Mitsubishi Chemical Corporation, total chlorine content: 5000 ppm, liquid at room temperature) (epoxy resin having an aromatic ring)

### Curing Agents (B)

The compounds used as the curing agents (B) in Examples, Comparative Example and Reference Examples are as follows.
(B-1): Liquid phenol novolak resin (trade name: MEH-8005, manufactured by UBE Corporation)
(B-2): 2,4-Diamino-6-[2′-methylimidazolyl-(1′)]ethyl-s-triazine (trade name: CUREZOL 2MZ-A, manufactured by SHIKOKU CHEMICALS CORPORATION)
(B-3): 2-Ethyl-4-methylimidazole (trade name: CUREZOL 2E4MZ, manufactured by SHIKOKU CHEMICALS CORPORATION)

### Inorganic Fillers (C)

The compounds used as the inorganic fillers (C) in Examples, Comparative Example and Reference Examples are as follows.
(C-1): Alumina filler (trade name: AG2030-SMO, manufactured by ADMATECHS COMPANY LIMITED, average particle size: 0.2 μm, maximum particle size: 3.0 μm, surface-treated with a silane coupling agent having a methacryloxy group)
(C-2): Silica filler (trade name: SE101G-SMO, manufactured by ADMATECHS COMPANY LIMITED, average particle size: 0.3 μm, maximum particle size: 3.0 μm, surface-treated with a silane coupling agent having a methacryloxy group)
(C-3): Silica nanofiller (trade name: ADMANANO YA050C-SM1, manufactured by ADMATECHS COMPANY LIMITED, average particle size: 50 nm, surface-treated with a silane coupling agent having a methacryloxy group)

### Carbon Black (D)

The compound used as the carbon black (D) in Examples, Comparative Example and Reference Examples is as follows.
(D-1): Carbon black (trade name: Special Black 4, manufactured by Orion Engineered Carbons)

“(D) Content” in Table 1 indicates the content (parts by mass) of the carbon black (D) based on the mass of the epoxy resin (A) taken as 100 parts by mass.

### Ion Trapping Agents (E)

The compounds used as the ion trapping agents (E) in Examples, Comparative Example and Reference Examples are as follows.
(E-1): Bismuth ion trapping agent (trade name: IXE-500, manufactured by TOAGOSEI CO., LTD., average particle size: 1.5 μm)
(E-2): Zirconium/bismuth ion trapping agent (trade name: IXEPLAS-B1, manufactured by TOAGOSEI CO., LTD., average particle size: 0.4 μm)
(E-3): Zirconium/bismuth ion trapping agent (trade name: IXE-6136, manufactured by TOAGOSEI CO., LTD., average particle size: 2.1 μm)
(E-4): Hydrotalcite ion trapping agent (trade name: SWMNA-015A-1, manufactured by TODA KOGYO CORP., average particle size: 0.2 μm)

### Silicone Additive (F)

The compound used as the silicone additive (F) in Examples, Comparative Example and Reference Examples are as follows.
(F-1): Silicone oil (trade name: SF8421, manufactured by Dow Corning Toray)

### Coupling Agent (G)

The compound used as the coupling agent (G) in Examples, Comparative Example and Reference Examples is as follows.
(G-1): 3-Glycidoxypropyltrimethoxysilane trade name: KBM403, manufactured by Shin-Etsu Chemical Co., Ltd.)

In Examples, Comparative Example and Reference Examples, properties of the liquid epoxy resin compositions and cured products were measured as follows.

### (Viscosity of the Liquid Epoxy Resin Compositions at 25° C.)

The viscosity (unit: Pa·s) of the resin compositions prepared was measured using a Brookfield HB rotational viscometer (equipped with spindle SC4-14) at 25° C. and 20 rpm. The results are described in Table 1.

### (Thixotropic Index (TI) of the Liquid Epoxy Resin Compositions)

The viscosity (unit: Pa·s) of the resin compositions prepared was measured under the same conditions as the above “viscosity of the compositions at 25° C.”, except that the rotational speed was 2 rpm. The viscosity obtained here was divided by the above “viscosity of the composition at 25° C.” to give the thixotropic index (TI) of the composition. The results are described in Table 1.

### (Viscosity of the Liquid Epoxy Resin Compositions at 120° C.)

With respect to each of the resin compositions prepared, the viscosity (unit: Pa·s) after application of oscillation at a frequency of 10 Hz at 120° C. for 40 seconds was measured at 120° C. using HAAKE MARS Rheometer in an oscillation strain control mode. The results are described in Table 1.

### (Gel Time of the Liquid Epoxy Resin Compositions)

The liquid epoxy resin compositions prepared were each dropped onto a stainless steel plate heated to 120±2° C. so as to form a circle having a diameter of about 5 mm. The time (unit: seconds) for the resin composition to become no longer thready was measured with a stopwatch while a metal needle was brought into contact with the composition at regular intervals. The gel time of the liquid epoxy resin composition of the present invention is preferably 30 to 600 seconds, more preferably 60 to 570 seconds, and particularly preferably 90 to 540 seconds. When the gel time is within this range, poor injectability due to the gelation of the liquid epoxy resin composition can be suppressed, the molding time at the time of compression molding does not become too long and the productivity can be enhanced.

### (Evaluation of the Injectability of the Liquid Epoxy Resin Compositions)

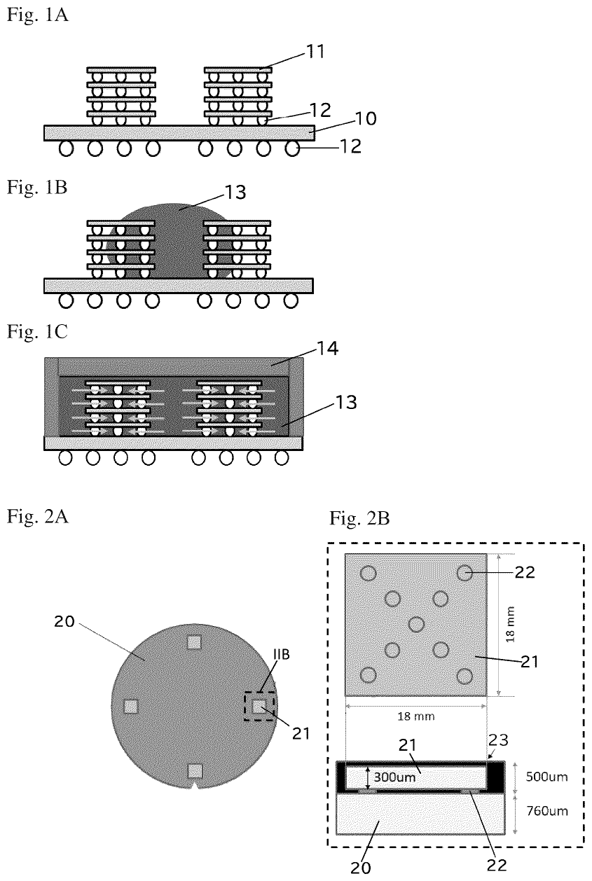

A silicon chip (length: 18 mm, width: 18 mm, thickness: 300 μm) was placed onto a silicon wafer (diameter: 300 mm, thickness: 760 μm) via nine spacers (disc shape, 1 to 2 mm in diameter and 20 μm in thickness). The spacers were arranged at regular intervals on the diagonal lines of the silicon chip (see FIG. 2B). In the above manner, four silicon chips were arranged at regular intervals near the outer periphery of the silicon wafer (see FIG. 2A).

The silicon wafer, together with the silicon chips and spacers, was placed in a compression molding machine (model number: WCM-300, manufactured by APIC YAMADA CORPORATION) having equipped therein a mold. Next, the liquid epoxy resin composition was charged into the mold, compression molding was carried out at a temperature of 120° C. and a pressure of 250 kN, and the liquid epoxy resin composition was cured by heating at this temperature for 400 seconds, to thereby form a layer of a cured product of the liquid epoxy resin composition having a thickness of 500 μm and entirely covering the silicon wafer (and having encapsulated therein the silicon chips and spacers described above).

The silicon wafer taken out from the compression molding machine, which was coated with the layer of the cured product, was cut at the positions slightly away from the outer edges of the silicon chips, to thereby obtain encapsulated products. The silicon chip, cured product and spacers were removed from the encapsulated products by surface polishing until the thickness of the cured product layer measured from the silicon wafer became approximately 10 μm, to thereby obtain test pieces for evaluating injectability.

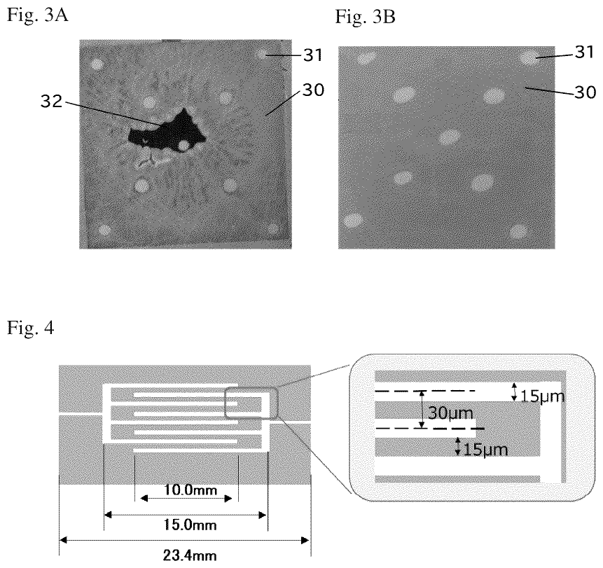

The polished side of the test pieces obtained was observed visually or under a microscope (magnification: 100 times). The injectability was evaluated as ◯ when no void was found in the test piece or the maximum width of the void found in the test piece was less than 100 μm (see FIG. 3B). The injectability was evaluated as x when the maximum width of the void found in the test piece was 100 μm or more (see FIG. 3A).

### (Fabrication of Cured Products)

Cured products were obtained by heating each of the prepared resin compositions with a dryer at 150° C. for 1 hour.

### (Thermal Conductivity of the Cured Products)

Using each of the prepared resin compositions, cured products were obtained by the method described in “Fabrication of cured products”. The cured products obtained were processed to prepare test pieces (10 mm in length, 10 mm in width, and 0.7 mm in thickness). The thermal conductivity of the test pieces was measured by a Xe-flash method using a thermal conductivity meter (LFA 447 NanoFlash, manufactured by NETZSCH Japan K.K.).

### (Biased HAST Test of the Cured Products)

A schematic view illustrating comb-shaped electrodes used in the evaluation of insulation reliability by a biased HAST test is given in FIG. 4. The comb-shaped electrodes were composed of a polyimide film substrate (thickness: 38 μm) and copper wiring patterned thereon (wiring width: 15 μm, line-to-line pitch: 30 μm, thickness: 8 μm, tin-plated (thickness: 0.2±0.05 μm)). The liquid epoxy resin composition was applied to the comb-shaped electrodes so that the thickness would be 150 μm and was heated with a dryer at 150° C. for 1 hour. The liquid epoxy resin composition on the comb-shaped electrodes was thus cured, to thereby obtain a test piece. The test piece was mounted on a HAST device (model number: PC-422R8, manufactured by HIRAYAMA Manufacturing Corporation). The electrical resistance was continuously monitored while applying a bias voltage of 3.5 V under the conditions of a relative humidity of 85% and a temperature of 130° C., and the time (unit: hr) from the start of the test until the occurrence of a short circuit (until the electrical resistance became 10 kΩ or less) was measured. The results are described in Table 1.

### (Content of Chloride Ions (Cl⁻) in the Cured Products)

A sample obtained by curing each of the prepared resin composition by heating at 150° C. for 1 hour was crushed into pieces of about 5 mm-square. 25 cm³ of ion exchanged water was added to 2.5 g of the sample, and the resultant mixture was placed in a PCT test tank (EHS-221M manufactured by ESPEC CORP., 121° C.±2° C./100% humidity/2 atm) for 20 hours and was then cooled to room temperature. The resultant extract was used as the test solution. The chloride ion concentration in the test solution obtained by the above procedure was measured with an ion chromatograph (Prominence HIC-NS, manufactured by Shimadzu Corporation, equipped with column IC-A1). The results of the evaluation of the chloride ion content are described in Table 1.

TABLE 1

| | | | | | | | | | Comp. | Ref. | Ref. | Ref. | Ref. |
|---|---|---|---|---|---|---|---|---|---|---|---|---|---|
| | | Ex. 1 | Ex. 2 | Ex. 3 | Ex. 4 | Ex. 5 | Ex. 6 | Ex. 7 | Ex. 1 | Ex. 1 | Ex. 2 | Ex. 3 | Ex. 4 |
| (A) | (A - 1) | 31.7 | 31.7 | 31.7 | 31.7 | 31.6 | 31.6 | 31.6 | 31.7 | 31.7 | 31.7 | 31.7 | 31.7 |
| | (A - 2) | 68.3 | 68.3 | 68.3 | 68.3 | 68.4 | 68.4 | 68.4 | 68.3 | 0.0 | 68.3 | 68.3 | 68.3 |
| | (A - 3) | 0.0 | 0.0 | 0.0 | 0.0 | 0.0 | 0.0 | 0.0 | 0.0 | 68.3 | 0.0 | 0.0 | 0.0 |
| (B) | (B - 1) | 7.7 | 7.7 | 7.7 | 7.7 | 7.7 | 7.7 | 7.7 | 7.7 | 7.7 | 7.7 | 7.7 | 7.7 |
| | (B - 2) | 4.1 | 4.1 | 4.1 | 4.1 | 4.1 | 4.1 | 4.1 | 4.1 | 4.1 | 4.1 | 4.1 | 4.1 |
| | (B - 3) | 0.4 | 0.4 | 0.4 | 0.4 | 0.4 | 0.4 | 0.4 | 0.5 | 0.4 | 0.5 | 0.4 | 0.4 |
| (C) | (C - 1) | 311.3 | 311.3 | 311.3 | 311.3 | 308.1 | 308.1 | 348.5 | 0.0 | 311.3 | 304.9 | 311.3 | 311.3 |
| | (C - 2) | 0.0 | 0.0 | 0.0 | 0.0 | 0.0 | 0.0 | 0.0 | 304.9 | 0.0 | 0.0 | 0.0 | 0.0 |
| | (C - 3) | 61.3 | 61.3 | 61.3 | 61.3 | 60.7 | 60.7 | 68.7 | 60.1 | 61.3 | 60.1 | 61.3 | 61.3 |
| (D) | (D - 1) | 1.0 | 1.0 | 0.2 | 1.5 | 1.0 | 1.0 | 1.0 | 1.0 | 1.0 | 1.0 | 1.0 | 1.0 |
| (E) | (E - 1) | 2.4 | 0.0 | 2.4 | 2.4 | 1.2 | 3.6 | 2.4 | 0.0 | 2.4 | 0.0 | 0.0 | 0.0 |
| | (E - 2) | 0.0 | 2.4 | 0.0 | 0.0 | 0.0 | 0.0 | 0.0 | 0.0 | 0.0 | 0.0 | 0.0 | 0.0 |
| | (E - 3) | 0.0 | 0.0 | 0.0 | 0.0 | 0.0 | 0.0 | 0.0 | 0.0 | 0.0 | 0.0 | 0.0 | 2.4 |
| | (E - 4) | 0.0 | 0.0 | 0.0 | 0.0 | 0.0 | 0.0 | 0.0 | 0.0 | 0.0 | 0.0 | 2.4 | 0.0 |
| (F) | (F - 1) | 0.5 | 0.5 | 0.5 | 0.5 | 0.5 | 0.5 | 0.5 | 0.5 | 0.5 | 0.5 | 0.5 | 0.5 |
| (G) | (G - 1) | 1.5 | 1.5 | 1.5 | 1.5 | 1.5 | 1.5 | 1.5 | 1.5 | 1.5 | 1.5 | 1.5 | 1.5 |

| | | | | | | | | | | | | |
|---|---|---|---|---|---|---|---|---|---|---|---|---|
| Total | 490.2 | 490.2 | 489.4 | 490.7 | 485.3 | 487.7 | 534.8 | 480.3 | 490.2 | 480.3 | 490.2 | 490.2 |
| (D) Content^{a} | 1.0 | 1.0 | 0.2 | 1.5 | 1.0 | 1.0 | 1.0 | 1.0 | 1.0 | 1.0 | 1.0 | 1.0 |
| Thermal conductivity (W/mK) | 1.1 | 1.1 | 1.1 | 1.1 | 1.1 | 1.1 | 1.2 | 0.7 | 1.1 | 1.1 | 1.1 | 1.1 |
| Chloride ion content (ppm) | 1.1 | 1.6 | 1.1 | 1.1 | 1.6 | 0.5 | 1.0 | 2.7 | 11.0 | 2.6 | 2.5 | 1.6 |
| 25° C. viscosity (Pa · s) | 160 | 142 | 150 | 164 | 168 | 223 | 450 | 110 | 170 | 84 | 181 | 150 |
| Thixotropic index | 2.2 | 2.3 | 2.1 | 2.2 | 2.1 | 1.9 | 2.3 | 1.2 | 2.1 | 2.3 | 2.3 | 2.2 |
| 120° C. viscosity (Pa · s) | 2.5 | 3.4 | 2.3 | 2.6 | 2.5 | 5.2 | 5.5 | 1.2 | 2.4 | 4.7 | 2.6 | 2.3 |
| Injectability | ◯ | ◯ | ◯ | ◯ | ◯ | ◯ | ◯ | ◯ | ◯ | ◯ | ◯ | X |
| Gel time (sec) | 217 | 213 | 218 | 215 | 216 | 219 | 210 | 232 | 213 | 213 | 220 | 214 |
| Biased HAST test (hr) | 171 | 205 | 180 | 167 | 151 | 193 | 168 | 123 | 43 | 121 | 119 | 165 |

^{a}Content (parts by mass) of the carbon black (D) based on the mass of the epoxy resin (A) taken as 100 parts by mass.

As apparent from Table 1, with respect to the liquid epoxy resin composition comprising the epoxy resin (A) (comprising the aliphatic epoxy resin represented by formula (I)), the curing agent (B), the inorganic filler (C) and the carbon black (D), when the inorganic filler (C) comprised a silica filler in combination with an alumina filler having an appropriate average particle size and the content of the carbon black (D) was appropriate, the liquid epoxy resin composition gave a cured product having a high thermal conductivity of 0.8 W/m·K or more (Examples 1 to 7 and Reference Examples 1 to 4). In an electronic component produced using such a liquid epoxy resin composition as a mold underfill material for TSV, release of heat generated during the driving of the component is improved.

In contrast, the liquid epoxy resin composition containing no alumina filler gave a cured product with low thermal conductivity (Comparative Example 1). In an electronic component produced using such a liquid epoxy resin composition as a mold underfill material for TSV, heat generated during the driving of the component is not satisfactorily released.

In the liquid epoxy resin compositions prepared using the epoxy resin (A) with a relatively low content of chloride ions, the amount of the detected chloride ion was inevitably and naturally small (Reference Example 2). In the cured products given by such liquid epoxy resin compositions, the time elapsed until the occurrence of short-circuiting in the biased HAST test was relatively long.

When the ion trapping agent (E) was added to such a liquid epoxy resin composition, the amount of the detected chloride ion was further decreased, and in the cured product given by such a liquid epoxy resin composition, the time elapsed until the occurrence of short-circuiting in the biased HAST test was extended (Examples 1 to 7 and Reference Example 4). However, when the ion trapping agent (E) was a hydrotalcite ion trapping agent, the time elapsed until the occurrence of short-circuiting did not significantly changed (Reference Example 3). When the ion trapping agent (E) had a large particle size, the liquid epoxy resin composition exhibited low injectability in spite of no significant increase in its viscosity (Reference Example 4).

On the other hand, the liquid epoxy resin composition prepared using the epoxy resin (A) with a relatively high content of chloride ions, large amount of chloride ion was detected in spite of the fact that the ion trapping agent (E) was added (Reference Example 1). In the cured product given by such a liquid epoxy resin composition, the time elapsed until the occurrence of short-circuiting in the biased HAST test was shortened.

Although not described in Table 1, with respect to injectability and reduction of warpage, the liquid epoxy resin composition in which the alumina filler in the inorganic filler (C) was surface-treated with a silane coupling agent having a methacryloxy group was superior to the liquid epoxy resin composition in which an alumina filler was surface-treated with a silane coupling agent having a phenylamino group.

The liquid epoxy resin composition of the present invention gives a cured product having high thermal conductivity. Thus, an electronic component manufactured using the liquid epoxy resin composition of the present invention as a mold underfill material for TSV satisfactorily releases heat generated during the driving of the component, even when the chip to wafer distance and/or chip to chip distance is/are short. In a semiconductor device including such electronic components, deterioration of performance due to heat is suppressed. Furthermore, in an electronic component that includes a cured product obtained by curing the liquid epoxy resin composition of the present invention, short circuiting does not occur over a long period of time in a biased HAST test. Thus, an electronic component manufactured using the liquid epoxy resin composition of the present invention as a mold underfill material for TSV exhibits satisfactory reliability, even when the bump to bump distance is short. Thus, the liquid epoxy resin composition of the present invention is highly suitable for use as a mold underfill material for TSV.

### REFERENCE SIGNS LIST

10 silicon wafer
11 silicon chip
12 bump
13 mold underfill material for TSV
14 mold
20 silicon wafer (diameter: 300 mm)
21 silicon chip
22 spacer (thickness: 20 μm)
23 cured product of mold underfill material for TSV
30 cured product of mold underfill material for TSV
31 spacer
32 void

What is claimed is:

1. A liquid epoxy resin composition for use as a mold underfill material for TSV, comprising the following (A) to (D):
(A) an epoxy resin;
(B) a curing agent;
(C) an inorganic filler consisting of a silica filler and an alumina filler; and
(D) carbon black, wherein
the epoxy resin (A) comprises an aliphatic epoxy resin represented by formula (I) below: 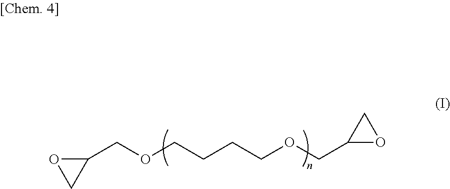
wherein n is an integer of 1 to 15,
the average particle size of the alumina filler is 0.1 m to 0.3 m,
the content of the carbon black (D) is 0.1 part by mass or more and 1.5 parts by mass or less, based on the mass of the epoxy resin (A) taken as 100 parts by mass, and
the liquid epoxy resin composition gives a cured product having a thermal conductivity of 0.8 W/m·K or more and less than 1.2 W/m·K.

2. The liquid epoxy resin composition according to claim 1, wherein
the liquid epoxy resin composition further comprises an ion trapping agent (E), and
the content of chloride ions (Cl⁻) is 0.01 ppm or more and less than 2.5 ppm, based on the total mass of the liquid epoxy resin composition, as measured by a process comprising subjecting to ion chromatography an extract obtained by immersing a cured product of the liquid epoxy resin composition crushed into pieces of 5 mm-square in water at a concentration of 0.1 g/cm³, a temperature of 121° C., a humidity of 100%, and 2 atm for 20 hours.

3. The liquid epoxy resin composition according to claim 2, wherein the ion trapping agent (E) comprises at least one member selected from bismuth compounds, zirconium compounds, and antimony compounds.

4. The liquid epoxy resin composition according to claim 2, wherein the average particle size of the ion trapping agent (E) is 0.01 m to 2 m.

5. The liquid epoxy resin composition according to claim 1, wherein
the total chlorine content in the aliphatic epoxy resin represented by formula (I) is 3000 ppm or less, and
the epoxy resin (A) comprises the aliphatic epoxy resin represented by formula (I) in combination with another epoxy resin having a total chlorine content of 3000 ppm or less.

6. The liquid epoxy resin composition according to claim 1, wherein the content of the inorganic filler (C) is 50 to 90 parts by mass, based on the total mass of the liquid epoxy resin composition taken as 100 parts by mass.

7. The liquid epoxy resin composition according to claim 1, wherein the epoxy resin (A) further comprises an epoxy resin having an aromatic ring in the molecule.

8. The liquid epoxy resin composition according to claim 1, wherein the curing agent (B) comprises at least one member selected from the group consisting of phenol compounds and nitrogen-containing heterocyclic compounds.

9. The liquid epoxy resin composition according to claim 1, further comprising a silicone additive (F).

10. The liquid epoxy resin composition according to claim 1, further comprising a coupling agent (G).

11. The liquid epoxy resin composition according to claim 1, wherein the content of particles of the inorganic filler (C) having a particle size of more than 1 m is less than 1.0 part by mass, based on the total mass of the inorganic filler (C) taken as 100 parts by mass.

12. The liquid epoxy resin composition according to claim 1, wherein the alumina filler is surface-treated with a silane coupling agent having a methacryloxy group or a phenylamino group.

13. A semiconductor package comprising a semiconductor element encapsulated with the liquid epoxy resin composition of claim 1.
